(19) United States
(12) Patent Application Publication
(10) Pub. No.: US 2004/0141387 A1
(43) Pub. Date: Jul. 22, 2004

(54) Semiconductor storage device

(75) Inventors: Hikoshi Hanji, Tokyo (JP); Yasuhiro Matsui, Hyogo (JP)

Correspondence Address: McDermott, Will & Emery, 600 13th Street, N.W., Washington, DC, 20005-3096, US

(73) Assignee: RENESAS TECHNOLOGY CORP.

(21) Appl. No.: 10/611,060

(22) Filed: Jul. 2, 2003

(30) Foreign Application Priority Data
Jan. 16, 2003 (JP) 2003-008833

(51) Int. Cl. G11C 7/00

(52) U.S. Cl. 365/200

(57) ABSTRACT

A semiconductor storage device is provided with a memory cell array and redundant cell arrays. Each of redundancy address program circuits that are provided for the respective redundant cell arrays produces a redundancy selection signal for selection of the corresponding redundant cell array. An address selection circuit selects an address of the memory cell array corresponding to an address selection signal if none of the redundancy address program circuits produce redundancy selection signals. Redundant cell array selecting circuits set priority ranks for the respective redundant cell arrays, and select only a redundant cell array having a highest priority rank at the time of receiving, from the redundancy address program circuits, redundancy selection signals for selection of two or more redundant cell arrays for the same address.

### BACKGROUND OF THE INVENTION

1. Field of the Invention

The present invention relates to a semiconductor storage device in which redundant cell arrays are provided as a relief measure against defective memory cells in a memory cell array.

2. Background Art

In general, for increase of the production yield and other purposes, semiconductormemory devices are provided with the redundant cell arrays such as redundant cell rows and redundant cell columns as the relief measure against the defective memory cells.

A technique is known in which in manufacture of such a semiconductor storage provided with the redundant cell arrays, defect relief for replacement of defective memory cells with the redundant cell arrays is performed in a plurality of steps in a wafer state and after assembling, for example (refer to Japanese Patent Laid-Open No. 2001-35186).

In conventional semiconductor storage devices, whether the redundant cell arrays are in use is judged by storing information indicating use/non-use of the redundant cell arrays in advance and later performing a test for reading out that information (refer to Japanese Patent Laid-Open No. 7-320495).

However, in the conventional semiconductor storage devices in which defect relief is performed in a plurality of steps, no defect-relief measure is available if a defective memory cell is detected again at an address where replacement by a redundant cell array was performed. This problem can be solved by storing defect address information in a tester system and a proper measure is taken according to a comparison/relief algorithm in a subsequent test. However, this raises another problem that construction of an expensive test system and increase in device capacity cause cost increase.

In the conventional semiconductor storage devices in which information indicating use/non-use of redundant cell arrays is stored in advance, a complex circuit is needed to judge whether redundant cell arrays are in use and a special test that is different from an ordinary memory cell array test needs to be performed to read out stored information.

### SUMMARY OF INVENTION

According to one aspect of the present invention, a semiconductor storage device is provided with a memory cell array and redundant cell arrays. Each of redundancy address program circuits that are provided for the respective redundant cell arrays produces a redundancy selection signal for selection of the corresponding redundant cell array. An address selection circuit selects an address of the memory cell array corresponding to an address selection signal if none of the redundancy address program circuits produce redundancy selection signals. Redundant cell array selecting circuits set priority ranks for the respective redundant cell arrays, and select only a redundant cell array having a highest priority rank at the time of receiving, from the redundancy address program circuits, redundancy selection signals for selection of two or more redundant cell arrays for the same address.

Other and further objects, features and advantages of the invention will appear more fully from the following description.

### BRIEF DESCRIPTION OF THE DRAWINGS

FIG. 1 is a flowchart showing defective memory cell detection and redundancy replacement according to a first embodiment of the present invention.

FIG. 2 is a schematic chart illustrating the corresponding redundancy replacement.

FIG. 3 shows a configuration of a semiconductor storage device having redundant cell arrays according to the first embodiment of the present invention.

FIG. 4 shows a configuration of a semiconductor storage device having redundant cell arrays according to a second embodiment of the invention.

### DETAILED DESCRIPTION OF THE PREFERRED EMBODIMENTS

### First Embodiment

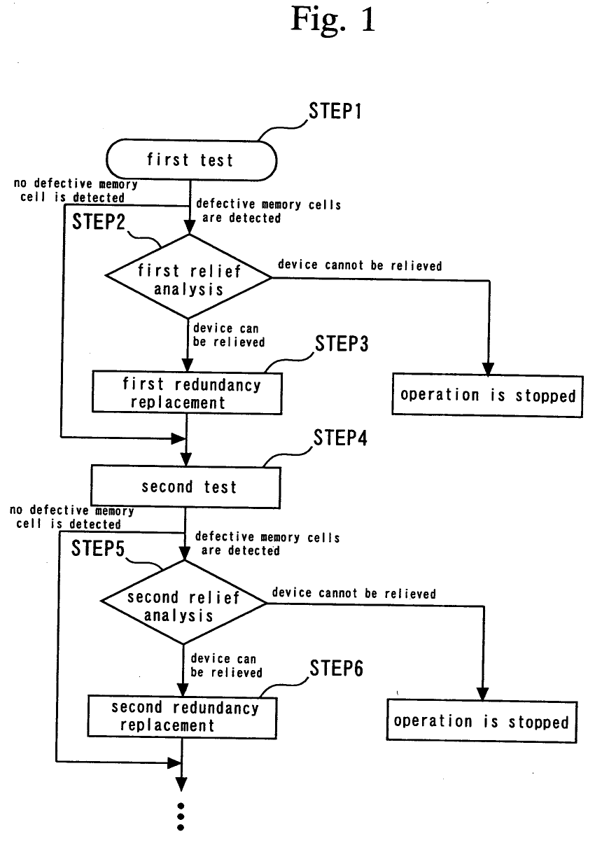

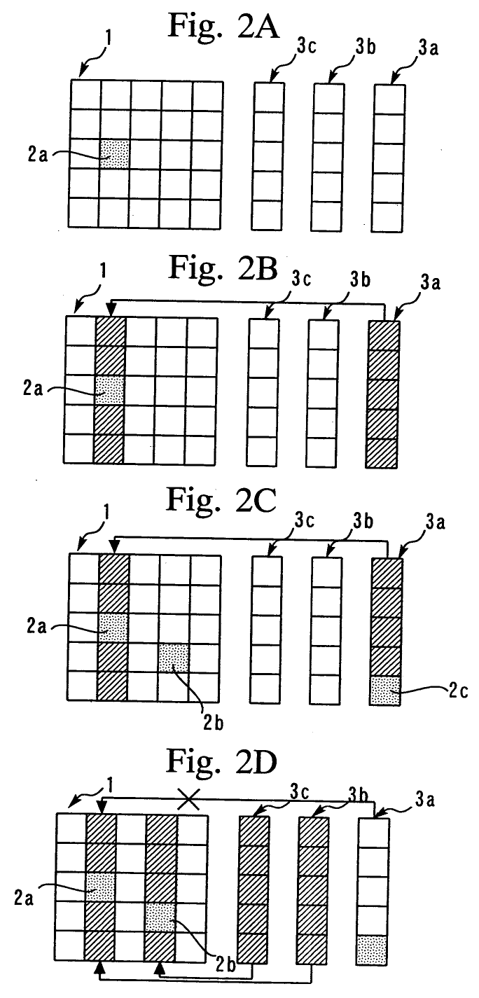

FIG. 1 is a flowchart showing defective memory cell detection and redundancy replacement according to a first embodiment of the present invention. FIGS. 2A-2D are schematic charts illustrating the corresponding redundancy replacement. In FIGS. 2A-2D, only a memory cell array 1 having a plurality of memory cell columns and redundant cell arrays 3a, 3b, and 3c are shown and other circuits etc. are omitted.

First, defective memory cells, if any, on the memory cell array 1 are detected by a first test (step-1) that is performed in a high-temperature state, for example. If defective memory cells are detected, the process goes to step-2. If no defective memory cell is detected, step-2 and step-3 are not executed.

In a first relief analysis (step-2), an analysis is made to judge whether the device can be relieved by replacing the memory cell columns including the detected defective memory cells with prepared redundant cell arrays. More specifically, if the number of memory cell columns including the defective memory cells is larger than the number of prepared redundancy cell arrays, it is judged that the device cannot be relieved and the operation on those memory cells is stopped. On the other hand, if the number of memory cell columns including the defective memory cells is smaller than the number of prepared redundancy cell arrays, it is judged that the device can be relieved and the process goes to step-3. FIG. 2A shows a case that one defective memory cell 2a has been detected in the memory cell array 1 and hence the number of memory cell columns to be replaced is one. Since the three redundant cell arrays 3a, 3b, and 3c are available, the device can be relieved.

In a first redundancy replacement (step-3), programming is performed to replace the memory cell columns including the defective memory cells of the memory cell array 1 with respective redundant cell arrays. FIG. 2B shows a case that the memory cell column including the defective memory cell 2a is replaced by the redundant cell array 3a.

Then, a second test (step-4) is performed in a low-temperature state, for example, to again detect defective memory cells, if any, in the memory cell array 1. However, for the memory cell columns that are replaced by the redundant cell arrays, defective memory cells, if any, in the replacement redundant cell arrays are detected. This makes it possible to detect, in the low-temperature state, new defective memory cells that were not generated in the high-temperature state. If defective memory cells are detected, the process goes to step-5. If no defective memory cell is detected, step-5 and step-6 are not executed.

Then, a second relief analysis (step-5) is performed in the same manner as the first one. FIG. 2C shows a case that a defective memory cell 2b has been found in the memory cell array 1 and a defective memory cell 2c has been found in the redundant cell array 3a and hence the two memory cell columns should be replaced. Since the two redundant cell arrays 3b and 3c remain unused, the device can be relieved.

In a second redundancy replacement (step-6), programming is performed to replace the memory cell columns and the redundant cell arrays including the newly detected defective memory cells with unused redundant cell arrays. FIG. 2C shows a case that the memory cell column including the defective memory cell 2b is replaced by the redundant cell array 3c and the memory cell column including the defective memory cell 2a and having a certain column address is replaced by the redundant cell array 3b instead of the redundant cell array 3a.

Defect relief can also be performed in another set of steps by performing defective memory cell detection and redundancy replacement in the same manner as described above. A semiconductor storage device having such a configuration as to enable repetitive defect relief for the same address will be described below in detail.

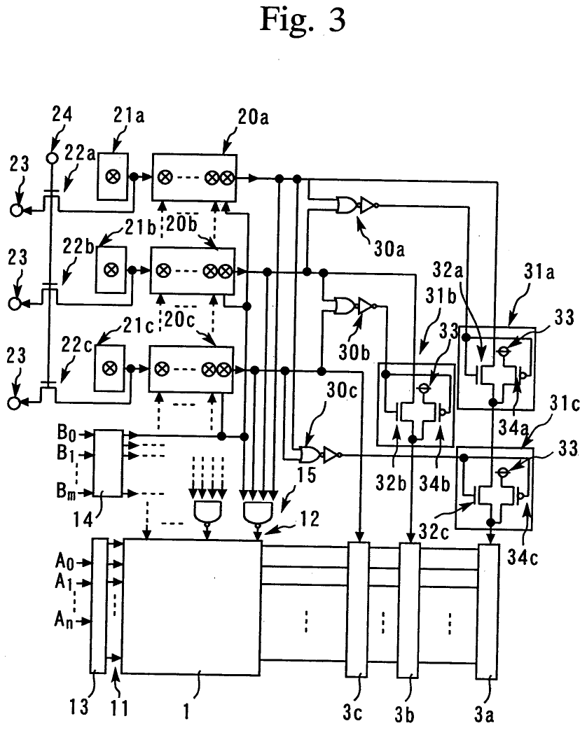

FIG. 3 shows a configuration of a semiconductor storage device having redundant cell arrays according to the first embodiment of the present invention. In a memory cell array 1, memory cells are provided at the respective crossing points of bit lines 11 and word lines 12. Redundant cell arrays 3a, 3b,and 3c are provided for replacement of defective memory cells in the memory cell array 1. A row decoder 13 selects a memory cell row of the memory cell array 1 at the time of decoding a corresponding one of row address signals A0-An. A column decoder 14 outputs an address selection signal for selecting a memory cell column of the memory cell array 1 at the time of decoding a corresponding one of column address signals B0-Bm.

Redundancy address program circuits 20a, 20b, and 20c are provided for the respective redundant cell arrays 3a, 3b, and 3 c. The outputs of all the column addresses of the column decoder 14 are connected to each of the redundancy address program circuits 20a, 20b, and 20c, and each of the redundancy address program circuits 20a, 20b, and 20c has fuses corresponding to the respective column addresses. By opening a fuse, the redundancy address program circuit 20a, 20b, or 20c is programmed to replace a memory cell column having the corresponding column address with the corresponding redundant cell array. If a received address selection signal coincides with a pre-programmed address, the redundancy address program circuits 20a, 20b, and 20c output a redundancy selection signal “L” for selecting the corresponding redundancy cell array.

NAND gates 15 as address selection circuits are provided for the respective word lines 12. The output of the corresponding address of the column decoder 14 and the outputs of the redundancy address program circuits 20a, 20b, and 20c are connected to the input terminals of each NAND circuit 15. The word line of the corresponding address is connected to the output terminal of each NAND circuit 15. Each NAND circuit 15 selects the columns address of the memory cell array 1 corresponding to an address selection signal when none of the redundancy address program circuits 20a, 20b, and 20c are outputting a redundancy selection signal “L.”

The output of the redundancy address program circuit 20a is connected to comparison circuits 30a and 30c and a selection circuit 31a. Similarly, the output of the redundancy address program circuit 20b is connected to comparison circuits 30a and 30b and a selection circuit 31b, and the output of the redundancy address program circuit 20c is connected to comparison circuits 30b and 30c and a selection circuit 31c. Each of the comparison circuits 30a, 30b, and 30c is configured in such a manner that an inverter is connected to the output of a NOR circuit. The outputs of the comparison circuits 30a, 30b, and 30c are connected to the respective selection circuits 31a, 31b, and 31c.

The redundancy address program circuit 20a is connected to the redundant cell array 3a via the selection circuits 31a and 31c. The redundancy address program circuit 20b is connected to the redundant cell array 3b via the selection circuit 31b. The redundancy address program circuit 20c is directly connected to the redundant cell array 3c. In this state, a selection circuit 31a has a switch 32a that connects the input and the output of the selection circuit 31a and a switch 34a that connects a voltage source 33 and the output of the selection circuit 31a. The switch 32a is turned on if the output of the comparison circuit 30a is at an H-level and is turned off if the output of the comparison circuit 30a is at an L-level. On the other hand, the switch 34a is turned on if the output of the comparison circuit 30a is at the L-level and is turned off if the output of the comparison circuit 30a is at the H-level. The configurations of the selection circuits 31b and 31c are similar to the configuration of the selection circuit 31a.

Redundancy enable circuits 21a, 21b, and 21c, are provided for the respective redundancy address program circuits 20a, 20b, and 20c. Each of the redundancy enable circuits 21a, 21b, and 21c outputs an enable signal to the corresponding redundancy address program circuit 20a, 20b, or 20c according to a preset program. The redundancy enable circuits 21a, 21b, and 21c are programmed by opening respective fuses respectively provided therein. When the fuse is opened, the redundancy enable circuits 21a, 21b, or 21c outputs an enable signal to the corresponding redundancy address program circuit 20a, 20b, or 20c.

First switches 22a, 22b, and 22c are provided for the respective redundancy enable circuits 21a, 21b, and 21c. Switched in response to a first test signal that is input to a terminal 24, the first switches 22a, 22b, and 22c supply output signals of the redundancy enable circuits 21a, 21b, and 21c to external terminals 23, respectively.

A redundancy replacement and an operation of the semiconductor storage device according to the first embodiment as described above will be described below. First, a description will be made of a case that no defective cells are detected in the memory cell array 1 in a first test (step-1) and hence no replacement by the redundant cell array 3a, 3b, and 3c is performed. In this case, the fuses of the redundancy enable circuits 21a, 21b, and 21c are not opened and hence none of the redundancy address program circuits 20a, 20b, and 20c are enabled. Thereby, the outputs of the redundancy address program circuits 20a, 20b, and 20c are at the H-level whichever column address is selected. In this state, the column decoder 14 makes the output of a column address to be selected at the H-level and the outputs of the other column addresses at the L-level. Therefore, the output of the NAND gate 15 corresponding to the selected column address becomes “L” and hence the memory cell column having that column address of the memory cell array 1 is selected. On the other hand, the outputs of all the comparison circuits 30a, 30b, and 30c become “H” and the signals “H” are input to all the redundant cell arrays 3a, 3b, and 3c, as a result of which none of the redundant cell arrays 3a, 3b, and 3c are selected.

Next, a description will be made of a case that a defective cell is detected at one column address of the memory cell array 1 in a first test (step-1). In the subsequent first relief analysis (step-2), a first test mode signal is input to the terminal 24 to turn on the first switches 22a, 22b, and 22c, whereby signals indicating whether or not the redundancy address program circuits 20a, 20b, and 20c are enabled is supplied to the output terminals 23, respectively. In this case, since the number of replacement-required column addresses is one and the number of unused redundant cell arrays is three, it is judged that relief is possible.

In the first redundancy replacement (step-3), the fuse of the redundancy enable circuit 21a and the fuse of the redundancy address program circuit 20a that corresponds to a replacement-required column address are opened. On the other hand, the fuses of the redundancy enable circuits 21b and 21c are not opened. A fuse is opened electrically or optically by using laser light.

If the replacement-required column address is selected by the column decoder 14 in such a state that the above redundancy replacement has been made, the output of the redundancy address program circuit 20a is at the L-level and the outputs of the redundancy address program circuits 20b and 20c are at the H-level. The output of the NAND gate 15 corresponding to the replacement-required column address becomes “H” and hence the memory cell array having that column address is not selected. On the other hand, the outputs of the comparison circuits 30a and 30c are at the L-level and the output of the comparison circuit 30b is at the H-level. Therefore, the signal “L” is input to the redundant cell array 3a and the signal “H” is input to the redundant cell arrays 3b and 3c, whereby the redundant cell array 3a is selected.

Next, a description will be made of a case that a defective memory cell is detected in the redundant cell array 3a in a second test (step-4) in a state that one column address of the memory cell array 1 is replaced by the redundant cell array 3a. In the subsequent second relief analysis (step-5), a relief analysis is performed in the same manner as the first one. In this case, since the number of replacement-required column addresses is one and the number of unused redundant cell arrays is two, it is judged that relief is possible. In a second redundancy replacement (step-6), the fuse of the redundancy enable circuit 21b is opened to enable the redundancy address program circuit 20b and the fuse of the redundancy address program circuit 20b that corresponds to a replacement-required column address is opened.

If the replacement-required column address is selected by the column decoder 14 in the state that the above redundancy replacement has been made, the outputs of the redundancy address program circuits 20a and 20b are at the L-level and the output of the redundancy address program circuit 20c is at the H-level. The output of the NAND gate 15 corresponding to the selected column address becomes “H” and hence the memory cell array having that column address is not selected. On the other hand, the output of the comparison circuits 30a is at the L-level and the outputs of the comparison circuits 30b and 30c is at the H-level. Therefore, the signal “H” is input to the redundant cell arrays 3a and 3c and the signal “L” is input to the redundant cell array 3b, whereby the redundant cell array 3b is selected in place of the redundant cell array 3b.

As described above, the comparison circuit 30a, 30b, and 30c and the selection circuits 31a, 31b, and 31c as redundant cell array selecting means set priority ranks for the redundant cell arrays 3a, 3b, and 3c, and select only a redundant cell array having a highest priority rank at the time of receiving redundancy selection signals for selecting two or more redundant cell arrays for the same address from the redundancy address program circuits 20a, 20b, and 20c.

Thereby, the semiconductor storage device according to this embodiment makes it possible to repeatedly perform defect relief for the same address without increasing any load of a tester system, and also to judge whether or not the redundant cell arrays 3a, 3b, and 3c are in use without the need for using a complex circuit or performing a special test.

### Second Embodiment

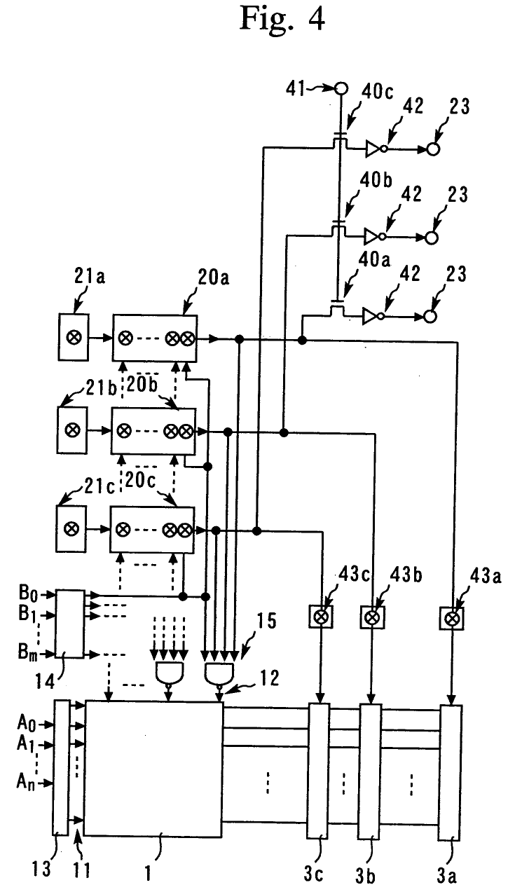

FIG. 4 shows a configuration of a semiconductor storage device having redundant cell arrays according to a second embodiment of the invention. Components in FIG. 4 having the same components in FIG. 3 are given the same reference numerals as the latter and will not be described.

As shown in FIG. 4, second switches 40a, 40b, and 40c are provided for respective redundancy address program circuits 20a, 20b, and 20c. Switched in response to a second test signal that is input to a terminal 41, the second switches 40a, 40b, and 40c supply output signals of the redundancy address program circuits 20a, 20b, and 20c to external terminals 23 via inverters 42a, 42b, and 42c, respectively.

Non-selection circuits 43a, 43b, and 43c having respective fuses are provided for respective redundant cell arrays 3a, 3b, and 3c. If its fuse is not opened, each of the non-selection circuits 43a, 43b, and 43c supplies an output signal of the corresponding redundancy address program circuit 20a, 20b, or 20c to the corresponding redundant cell array 3a, 3b, or 3c. On the other hand, if its fuse is opened, each of the non-selection circuits 43a, 43b, and 43c renders the corresponding redundant cell array 3a, 3b, or 3c in a non-selection state irrespective of the contents of an output signal of the corresponding redundancy address program circuit 20a, 20b, or 20c.

A redundancy replacement and an operation of the semiconductor storage device according to the second embodiment as described above will be described below. This semiconductor storage device of the second embodiment performs redundancy relief in the same manner as in the first embodiment without opening the fuses of the non-selection circuits 43a, 43b, and 43c to first redundancy replacement (step-3).

Next, a description will be made of a case that a defective memory cell is detected in the redundant cell array 3a in a second test (step-4) in a state that one column address of the memory cell array 1 is replaced by the redundant cell array 3a. In the subsequent second relief analysis (step-5), a second test mode signal is input to the terminal 41 to turn on the second switches 40a, 40b, and 40c. The column decoder 14 outputs address selection signals of the respective column addresses and signals that are output from the redundancy address program circuits 20a, 20b, and 20c accordingly are taken out via the external terminals 23 and observed. Thereby, information indicating a relationship between replacement-required addresses and redundant cell arrays used for replacement can be obtained. In this example, it can be recognized that one column address is replaced by the redundant cell array 3a.

In the second redundancy replacement (step-6), as in the case of the first embodiment, the fuse of the redundancy enable circuit 21b is opened to enable the redundancy address program circuit 20b and the fuse of the redundancy address program circuit 20b corresponding to a replacement-required column address is opened. On the basis of the information that was obtained in the second relief analysis (step-5), it is recognized that in this state both of the redundant cell arrays 3a and 3b will be selected for the same address. Therefore, the fuse of the non-selection circuit 43a is opened, whereby the redundant cell array 3a is rendered in a non-selection state irrespective of the contents of the output signal of the redundancy address program circuit 20a .

If the replacement-required column address is selected by the column decoder 14 in the state that the above redundancy replacement has been performed, the outputs of the redundancy address program circuits 20a and 20b are at the L-level and the output of the redundancy address program circuit 20c is at the H-level. The output of the NAND gate 15 corresponding to the selected column address becomes “H” and hence the memory cell array 1 having that column address is not selected. On the other hand, the signal “H” is input to the redundant cell arrays 3a and 3c and the signal “L” is input to the redundant cell array 3b, whereby the redundant cell array 3b is selected in place of the redundant cell array 3b.

Thereby, the semiconductor storage device according to this embodiment makes it possible to repeatedly perform defect relief for the same address without increasing any load of a tester system, and also to judge whether or not the redundant cell arrays 3a, 3b, and 3c are in use without the need for using a complex circuit or performing a special test.

Although the above embodiments are directed to the case that the three redundant cell arrays are provided, the present invention can also be applied to cases that four or more redundant cell arrays are provided. And the present invention can also be applied to a case that redundancy replacement is performed on a row address of a memory cell array. Further, a method of changing the states of the redundancy address program circuits and the redundancy enable circuits to effect redundancy replacement is not limited to using electrical fuses and opening fuses using laser light; for example, a flash memory or the like may be used. The replacement using electrical fuses or a flash memory enables complete relief by performing replacement and a test again in the same test step when, for example, a defect has been found in a replacement destination. More efficient redundancy replacement can be performed by not using any defective redundant cell arrays by testing all the redundant cell arrays in advance.

The features and advantages of the present invention may be summarized as follows.

As described above, the present invention makes it possible to perform defect relief repeatedly for the same address without increasing any load of a tester system and to judge whether or not redundant cell arrays are in use without the need for using a complex circuit or performing a special test.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2003-008833, filed on Jan. 16, 2003 including specification, claims, drawings and summary, on which the Convention priority of the present application is based, are incorporated herein by reference in its entirety.

What is claimed is:

1. A semiconductor storage device comprising:
a memory cell array;
a plurality of redundant cell arrays for relieving the device by replacing defective memory cells in the memory cell array;
a decoder for producing an address selection signal for selection of an address of the memory cell array;
a plurality of redundancy address program circuits provided at the respective redundant cell arrays, each for producing a redundancy selection signal for selection of the corresponding redundant cell array if the address selection signal coincides with a pre-programmed address;
an address selection circuit for selecting the address of the memory cell array corresponding to the address selection signal if none of the redundancy address program circuits produce the redundancy selection signals; and
redundant cell array selecting means for setting priority ranks for the respective redundant cell arrays, and for selecting only a redundant cell array having a highest priority rank at the time of receiving, from the redundancy address program circuits, the redundancy selection signals for selection of two or more redundant cell arrays for the same address.

2. A semiconductor storage device comprising:
a memory cell array;
a plurality of redundant cell arrays for relieving the device by replacing defective memory cells in the memory cell array;
a decoder for producing an address selection signal for selection of an address of the memory cell array;
a plurality of redundancy address program circuits provided at the respective redundant cell arrays, each for producing a redundancy selection signal for selection of the corresponding redundant cell array if the address selection signal coincides with a pre-programmed address;
an address selection circuit for selecting the address of the memory cell array corresponding to the address selection signal if none of the redundancy address program circuits produce the redundancy selection signals; and
a plurality of non-selection circuits provided at the respective redundant cell arrays and having respective fuses, each for supplying the redundancy selection signal of the corresponding redundancy address program circuit to the corresponding redundancy cell array if the fuse thereof is not opened, and for rendering the corresponding redundancy cell array in a non-selection state irrespective of a content of the redundancy selection signal of the corresponding redundancy address program circuit if the fuse thereof is opened.

3. The semiconductor storage device according to claim 1, further comprising:
a plurality of redundancy enable circuits provided for the respective redundancy address program circuits, each for supplying or not supplying an enable signal to the corresponding redundancy address program circuit according to a program that has been set in advance; and
a plurality of first switches provided for the respective redundancy enable circuits, for outputting outside the enable signals, if any, of the redundancy enable circuits, respectively, when switched in response to a first test signal.

4. The semiconductor storage device according to claim 2, further comprising a plurality of second switches provided for the respective redundancy address program circuit, for outputting outside the redundancy selection signals of the redundancy address program circuits, respectively, when switched in response to a second test signal.
